(19) United States
(12) Patent Application Publication
(10) Pub. No.: US 2008/0242047 A1
(43) Pub. Date: Oct. 2, 2008

(54) METHOD OF FORMING ISOLATION STRUCTURE OF SEMICONDUCTOR MEMORY DEVICE

(75) Inventors: Wan Sup Shin, Seoul (KR); Doo Ho Choi, Icheon-si (KR); Kwang Hyun Yun, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/053,482

(22) Filed: Mar. 21, 2008

(30) Foreign Application Priority Data
Mar. 27, 2007 (KR) 10-2007-029621

(51) Int. Cl. H01L 21/02

(52) U.S. Cl. 438/438; 257/E21.002

(57) ABSTRACT

The present invention relates to a method of forming isolation layers of a semiconductor memory device. According to a method of forming isolation layers of a semiconductor memory device in accordance with an aspect of the present invention, a tunnel dielectric layer, a conductive layer for a floating gate, a buffer oxide layer, and a pad nitride layer are sequentially formed over a semiconductor substrate. A trench is formed by selectively etching the pad nitride layer, the buffer oxide layer, the conductive layer for the floating gate, the tunnel dielectric layer, and the semiconductor substrate. The trench is gap-filled by forming a dielectric layer over the entire structure including the trench. A curing process is performed using a pre-heated curing gas. A height of the isolation layers is controlled by performing a cleaning process.

### CROSS-REFERENCES TO RELATED APPLICATIONS

The present application claims priority to Korean patent application number 10-2007-029621, filed on Mar. 27, 2007, which is incorporated by reference in its entirety.

### BACKGROUND OF THE INVENTION

The present invention relates to a method of forming isolation structure of a semiconductor memory device and, more particularly, to a method of forming an isolation structure of a semiconductor memory device, which can increase the effect of a curing process of the isolation layer.

In a semiconductor circuit, it is necessary to electrically isolate unit elements (e.g., transistors, diodes, resistors, etc.), which are formed over a semiconductor substrate. This isolation process is the process of an initial stage in all the semiconductor fabrication processes and determines the size of an active region and process margin of a subsequent step.

As a method of forming such element isolation, LOCal Oxidation of Silicon (hereinafter, referred to as “LOCOS”) has generally been used. However, with LOCOS element isolation, oxygen is penetrated into the lateral portion of a pad oxide layer under a nitride layer used as a mask upon selective oxidization of a semiconductor substrate, so that a bird's beak is generated at the corners of a field oxide layer. This bird's beak causes the field oxide layer to extend into the active region by as long as the length of the bird's beak, resulting in a shortened channel length and an increased threshold voltage. Consequently, a problem arises because the electrical characteristic of the transistor, etc. is degraded.

On the other hand, a Shallow Trench Isolation (hereinafter, referred to as “STI”) process has emerged as an isolation process that is able to solve instable factors of the process degradation of the field oxide layer according to a reduction in the design rule of the semiconductor device and problems such as a reduction in the active region due to the bird's beak.

FIG. 1 is a sectional view illustrating a conventional method of forming an isolation structure of a semiconductor memory device.

Referring to FIG. 1, a tunnel dielectric layer 11 and a polysilicon layer 12 for a floating gate are formed over a semiconductor substrate 10. The polysilicon layer 12 and the tunnel dielectric layer 11 are selectively etched, thus exposing isolation regions of the semiconductor substrate 10. The exposed semiconductor substrate 10 is etched in order to form trenches 13. The trenches 13 are gap filled with a dielectric layer, forming an isolation structure 14.

Before the isolation structure 14 are formed, a series of sacrificial oxidization processes of the trench (13) sidewalls (for the purpose of removing etch defects on the semiconductor surface by dry etch) and a series of reoxidization processes of the trench (13) sidewalls are performed. However, the processes are omitted for simplification.

Recently, in order to increase the degree of integration of semiconductor memory devices, sub-60 nm technology has been used. In line with this tendency, semiconductor memory employing the SA-STI (Self-Aligned Shallow Trench Isolation) process is difficult to secure gap-fill margin employing a HDP (High Density Plasma) layer. Thus, a SOD (Spin On Dielectric) layer is used in order to secure such gap-fill margin.

### BRIEF SUMMARY OF THE INVENTION

The present invention relates to a method of forming an isolation structure of a semiconductor memory device, in which it can form a stable isolation structure irrespective of a trench depth, improve the electrical characteristics of the device, and control the EFH (Effective Field oxide Height) stably, by forming a liner oxide layer within a trench, coating a SOD layer and then performing a SOD curing process by pre-heating a source gas in consideration of a trench depth.

According to an aspect of the present invention, there is provided a method of forming an isolation structure of a semiconductor memory device including: sequentially forming a tunnel dielectric layer, a conductive layer for a floating gate, a buffer oxide layer, and a pad nitride layer over a semiconductor substrate, forming a trench by selectively etching the pad nitride layer, the buffer oxide layer, the conductive layer for the floating gate, the tunnel dielectric layer, and the semiconductor substrate, gap-filling the trench by forming a dielectric layer over the entire structure including the trench, performing a curing process using a pre-heated curing gas, and controlling a height of the isolation structure by performing a cleaning process.

Before the dielectric layer is formed after the formation of the trench, a wall oxide layer and a liner oxide layer over the entire structure including the trench are sequentially formed.

The conductive layer for the floating gate includes a dual layer consisting of an amorphous polysilicon layer not containing impurities and a polysilicon layer containing impurities.

The curing gas may employ H₂O, O₂, NH₃, N₂O, NO, N₂, Ar or He. The H₂O gas may be generated using a wet oxidization torch type, a WVG (Water Vapor Generator), a CWVG (Catalytic Water Vapor Generator) or a radical oxidization method.

The curing process may employ the curing gas pre-heated using a pre-heating system. The pre-heating system may employ a PAC (Pre-Activation Chamber, TEL Corporation), a coil type torch or a lamp type torch. The pre-heating system enables metal resistance heating or lamp heating in a tube or chamber type of a quartz material. The curing process may be performed in a temperature range of normal temperature to 1100 degrees Celsius and at a pressure range of ˜10⁻⁷ to 760 Torr.

### BRIEF DESCRIPTION OF THE DRAWINGS

FIG. 1 is a sectional view illustrating a conventional method of forming an isolation structure of a semiconductor memory device;

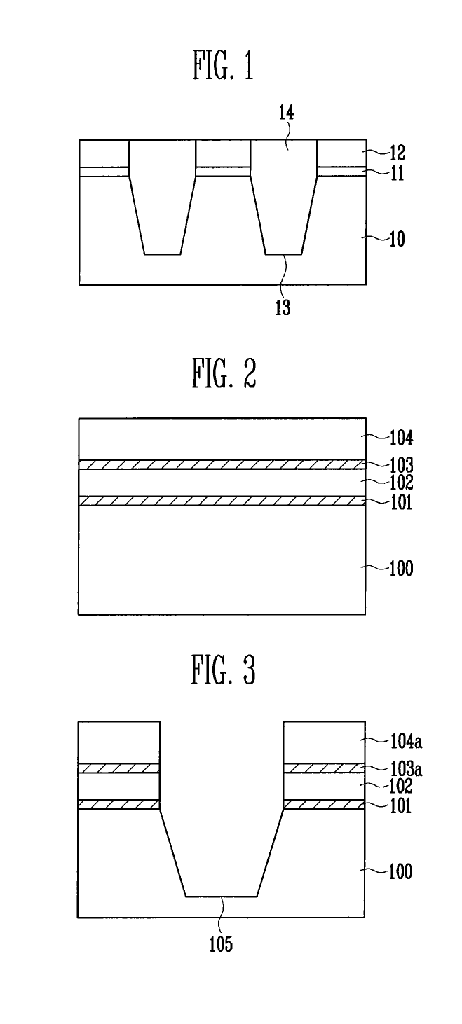

FIGS. 2 to 4 and FIG. 6 to 7 are sectional views illustrating a method of forming an isolation structure of a semiconductor memory device according to an embodiment of the present invention; and

FIG. 5 is a schematic view illustrating a curing process according to an embodiment of the present invention.

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

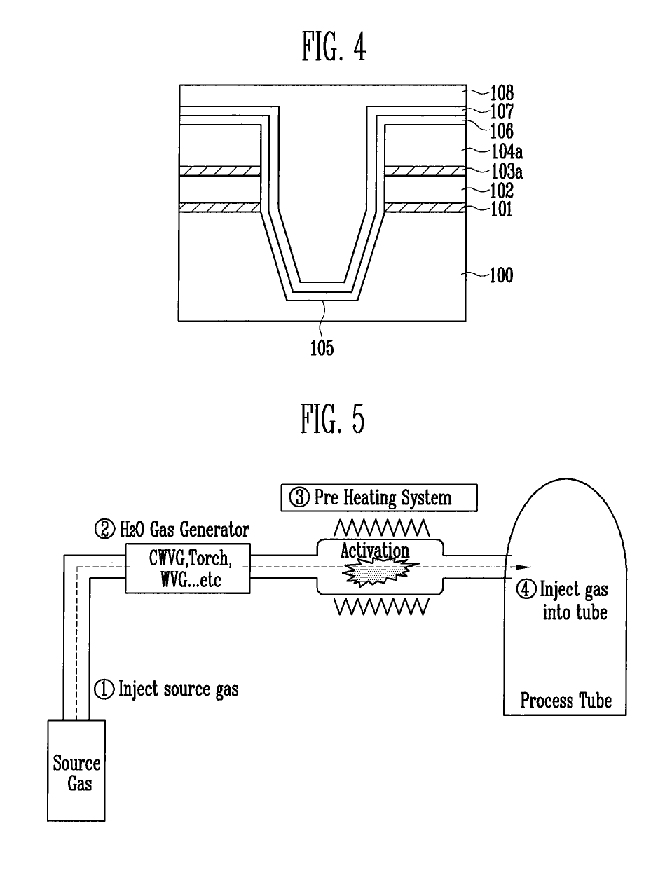

FIGS. 2 to 4 and FIG. 6 to 7 are sectional views illustrating a method of forming an isolation structure of a semiconductor memory device according to an embodiment of the present invention.

Referring to FIG. 2, a tunnel dielectric layer 101, a conductive layer 102 for a floating gate, a buffer oxide layer 103, and a pad nitride layer 104 are sequentially formed over a semiconductor substrate 100. The conductive layer 102 for the floating gate may be formed of a dual layer, including an amorphous polysilicon layer not containing impurities and a polysilicon layer containing impurities. The conductive layer 102 may be formed in a temperature range of 480 to 550 degrees Celsius using SiH₄ gas and PH₃ gas as a source gas. The conductive layer 102 may be formed in-situ using a LP-CVD method at a pressure range of 0.1 to 1 Torr. Further, the conductive layer 102 may be deposited to a thickness of 500 to 1500 angstroms. The buffer oxide layer 103 may be formed to a thickness of 30 to 50 angstroms so as to mitigate stress with the conductive layer 102 and the pad nitride layer 104. The buffer oxide layer 103 may be formed using one of HTO, TEOS and DCS-HTO methods.

Referring to FIG. 3, hard mask patterns 104a and 103a are formed by selectively etching the pad nitride layer 104 and the buffer oxide layer 103. The conductive layer 102, the tunnel dielectric layer 101 and the semiconductor substrate 100 are sequentially etched using an etch process employing the hard mask patterns 104a and 103a, thus forming a trench 105.

Referring to FIG. 4, a wall oxide layer 106 is formed over the entire structure including the trench 105 by performing an oxidization process. The wall oxide layer 106 functions to mitigate etch damage generated during the trench etch process and reduce the critical dimension (CD) of the active region. The wall oxide layer 106 may be formed of the conductive layer 102 for the floating gate using a radical oxidization method. The wall oxide layer 106 may be formed to a thickness of 30 to 50 angstroms. A liner oxide layer 107 is formed over the entire structure including the wall oxide layer 106. The liner oxide layer 107 may be formed to a thickness of about 600 to 1200 angstroms using a PE-CVD method in a temperature range of 400 to 700 degrees Celsius. SOD material is coated over the entire structure including the liner oxide layer 107, thus forming a SOD layer 108 to gap fill the trench 105. A curing process is then carried out.

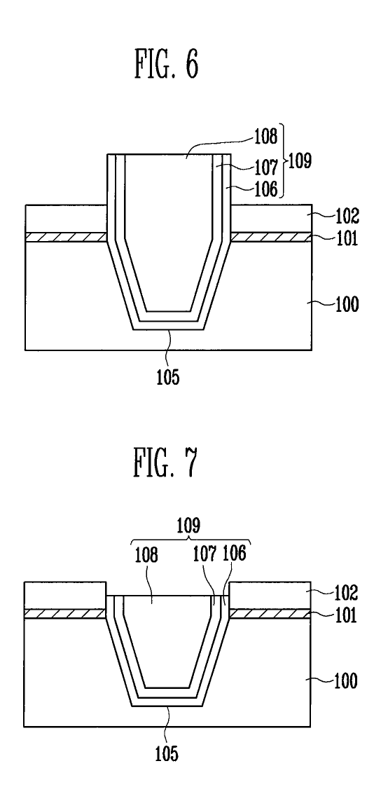

FIG. 5 is a schematic view illustrating a curing process according to an embodiment of the present invention.

Referring to FIG. 5, the curing process may be performed using H₂O, O₂, NH₃, N₂O, NO, N₂, Ar or He as a curing gas. The H₂O gas may be generated using a wet oxidization torch type, a WVG (Water Vapor Generator), a CWVG (Catalytic Water Vapor Generator) or a radical oxidization method. The curing gas is cured using a pre-heating system before it is injected into a tube. The pre-heating system may employ a PAC (Pre-Activation Chamber, TEL Corporation), a coil type torch or a lamp type torch. Further, the pre-heating system may enable metal resistance heating or lamp heating in a tube or chamber type of a quartz material. Before the curing gas is injected into the tube, the curing gas is pre-heated in order to raise the activation energy of molecules, so the curing effect of the SOD layer 108 formed at the bottom of the trench 105 can be increased. The curing process may be performed in a temperature range of room temperature to 1100 degrees Celsius. The curing process may be performed at a pressure range of 10⁻⁷ to 760 Torr.

Referring to FIG. 6, a CMP process is performed in order to expose the top surface of the hard mask pattern 104a, so the SOD layer 108 remains only within the trench and therefore an isolation structure 109 having the layers 106, 107 and 108 are formed. The mask patterns 104a and 103a are removed by an etching process.

Referring to FIG. 7, a cleaning process is performed in order to control a target so that the EFH becomes a desired level, thus etching the top surfaces of the isolation structure 109. The layers 106, 107 and 108 have their top and bottom uniformly formed by the curing process, so the etch rate of the top and bottom surfaces becomes uniform.

As described above, according to the present invention, the liner oxide layer is formed within the trench, the SOD layer is coated, and the SOD curing process is then performed by pre-heating a source gas in consideration of a trench depth. Accordingly, stable isolation layers can be formed irrespective of a trench depth, the electrical characteristic of a device can be improved, and the EFH can be controlled stably.

The present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

What is claimed is:

1. A method of forming an isolation structure of a semiconductor memory device, the method comprising:
forming a tunnel dielectric layer over a semiconductor substrate, a conductive layer for a floating gate over the tunnel dielectric layer, a buffer oxide layer over the conductive layer, and a pad nitride layer over the buffer oxide layer;
forming a trench by etching the pad nitride layer, the buffer oxide layer, the conductive layer for the floating gate, the tunnel dielectric layer, and the semiconductor substrate;
gap-filling the trench by forming a dielectric layer over the pad nitride layer;
performing a curing process using a pre-heated curing gas; and
controlling a height of the isolation layers by performing a cleaning process.

2. The method of claim 1, further comprising sequentially forming a wall oxide layer and a liner oxide layer over the entire structure including the trench, before the dielectric layer is formed after the formation of the trench.

3. The method of claim 1, wherein the conductive layer for the floating gate includes an amorphous polysilicon layer not containing impurities and a polysilicon layer containing impurities.

4. The method of claim 1, wherein the curing gas employs H₂O, O₂, NH₃, N₂O, NO, N₂, Ar or He.

5. The method of claim 4, wherein the H₂O gas is generated using a wet oxidization torch type, a Water Vapor Generator (WVG), a Catalytic Water Vapor Generator (CWVG) or a radical oxidization method.

6. The method of claim 1, wherein the curing process employs the curing gas pre-heated using a pre-heating system.

7. The method of claim 6, wherein the pre-heating system employs a pre-activation chamber, a coil type torch or a lamp type torch.

8. The method of claim 6, wherein the pre-heating system enables metal resistance heating or lamp heating in a tube or chamber type of a quartz material.

9. The method of claim 1, wherein the curing process is performed in a temperature range of room temperature to 1100 degrees Celsius and at a pressure range of 10⁻⁷ to 760 Torr.

10. A method of forming isolation layers of a semiconductor memory device, the method comprising:
forming a trench by etching an isolation region of a semiconductor substrate;
gap-filling the trench using a dielectric layer;
performing a curing process using a curing gas pre-heated by a pre-heating system; and
controlling a height of the isolation layers by performing a cleaning process.
